(19) United States
(12) Patent Application Publication
(10) Pub. No.: US 2008/0242098 A1
(43) Pub. Date: Oct. 2, 2008

(54) Method for forming pattern in semiconductor device

(75) Inventors: Ki-Won Nam, Kyoungki-do (KR); Ky-Hyun Han, Kyoungki-do (KR)

Correspondence Address: BLAKELY SOKOLOFF TAYLOR & ZAFMAN LLP, 1279 OAKMEAD PARKWAY, SUNNYVALE, CA, 94085-4040, US

(73) Assignee: Hynix Semiconductor Inc.

(21) Appl. No.: 11/823,797

(22) Filed: Jun. 28, 2007

(30) Foreign Application Priority Data
Mar. 26, 2007 (KR) 2007-0028996

(51) Int. Cl. H01L 21/311

(52) U.S. Cl. 438/703; 257/E21.002

(57) ABSTRACT

A method for forming a pattern in a semiconductor device includes forming an etch target layer over a substrate, forming a hard mask pattern over the etch target layer, and etching the etch target layer using the hard mask pattern as an etch mask and a gas mixture including a fluorine (F)-based gas and a bromine (Br)-based gas as an etch gas to form a target pattern.

### CROSS-REFERENCE TO RELATED APPLICATIONS

The present invention claims priority of Korean patent application number 2007-0028996, filed on Mar. 26, 2007, which is incorporated by reference in its entirety.

### BACKGROUND OF THE INVENTION

The present invention relates to a method for fabricating a semiconductor device, and more particularly, to a method for forming a pattern in semiconductor device.

The thickness of a photoresist pattern used in a mask process is decreased as patterns are scaled down to meet the large-scale of integration of semiconductor devices. Therefore, currently in most processes, a hard mask is interposed under a photoresist pattern, and used as an etch mask. Hence, as an example of pattern forming technology using a hard mask, a bit line pattern forming method is described briefly referring to FIG. 1.

FIG. 1 is a cross sectional view illustrating a conventional method for forming a bit line pattern in a semiconductor device. A patterned bit line barrier layer 11, a patterned bit line conductive layer 12 and a patterned hard mask nitride layer 13 are sequentially formed over a substrate 10 where predetermined bottom structures are already formed. The patterned bit line barrier layer 11 is formed in a Ti (titanium)/TiN (titanium nitride) structure, and the patterned bit line conductive layer 12 has a structure where a tungsten layer and a polysilicon layer are laminated over each of them.

In more detail of this patterning, although not illustrated, a bit line barrier layer, a bit line conductive layer and a hard mask nitride layer are sequentially formed over the substrate. Photoresist pattern (not shown) is formed over the hard mask nitride layer, which is, in turn, etched using this photoresist pattern as an etch mask to form the patterned hard mask nitride layer 13. The bit line conductive layer and the bit line barrier layer 11 are etched using the patterned hard mask nitride layer 13 as an etch barrier to form the patterned bit line conductive layer 12 and the patterned bit line barrier 11. Consequently, this patterning provides a bit line 14 laminated with the patterned bit line barrier layer 11, the patterned bit line conductive layer 12 and the patterned hard mask nitride mask 13.

However, the above described method may have the following limitations. When the hard mask nitride layer is etched, a top portion of the hard mask nitride layer is likely to be damaged due to the lack of the etch margin resulting from a current trend in decreasing thickness of photoresist. When lower layers (e.g., the bit line conductive layer and the bit line barrier layer) are etched using the patterned hard mask nitride layer as an etch mask, damage and loss of the hard mask nitride layer may become severe.

FIG. 2 illustrates a top view of a bit line pattern. When a bit line pattern in formed based on the conventional method, a top portion of a hard mask nitride layer may sustain a loss due to the damage on the top portion. As a result, the hard mask nitride layer may have an abnormal shape. When contact holes are formed by following a self aligned contact (SAC) process, the loss of the hard mask nitride may cause an insufficient SAC margin and SAC inferiority which may further lower the safety of the process.

### SUMMARY OF THE INVENTION

Embodiments of the present invention are directed towards providing a method for forming a pattern in a semiconductor device, which can minimize damage and loss of a hard mask in forming the pattern using the hard mask including a nitride-based material by etching a lower layer formed beneath the hard mask using fluorine (F)-based gas and bromine (Br)-based gas.

In accordance with an aspect of the present invention, there is provided a method for forming a pattern in a semiconductor device. The method includes forming an etch target layer over a substrate, forming a hard mask pattern over the etch target layer, and etching the etch target layer using the hard mask pattern as an etch mask and a gas mixture including a fluorine (F)-based gas and a bromine (Br)-based gas as an etch gas to form a target pattern.

### BRIEF DESCRIPTION OF THE DRAWINGS

FIG. 1 is a cross-sectional view illustrating a method for forming a pattern in a semiconductor device.

FIG. 2 illustrates a top view of a bit line pattern.

FIG. 3 is a cross-sectional view illustrating a method for forming a pattern (e.g., a bit line pattern) in a semiconductor device in accordance with an embodiment of the present invention.

FIG. 4 illustrates a top view of a bit line pattern.

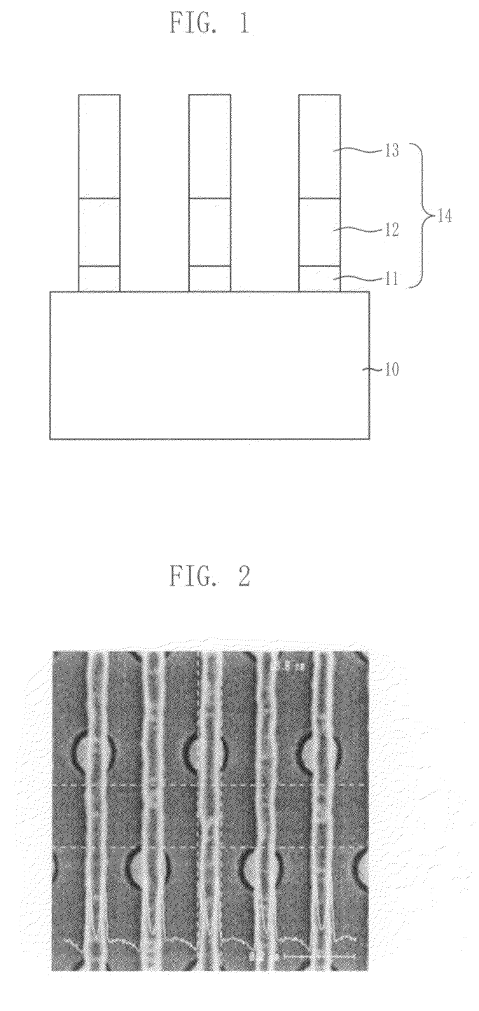

### DESCRIPTION OF SPECIFIC EMBODIMENTS

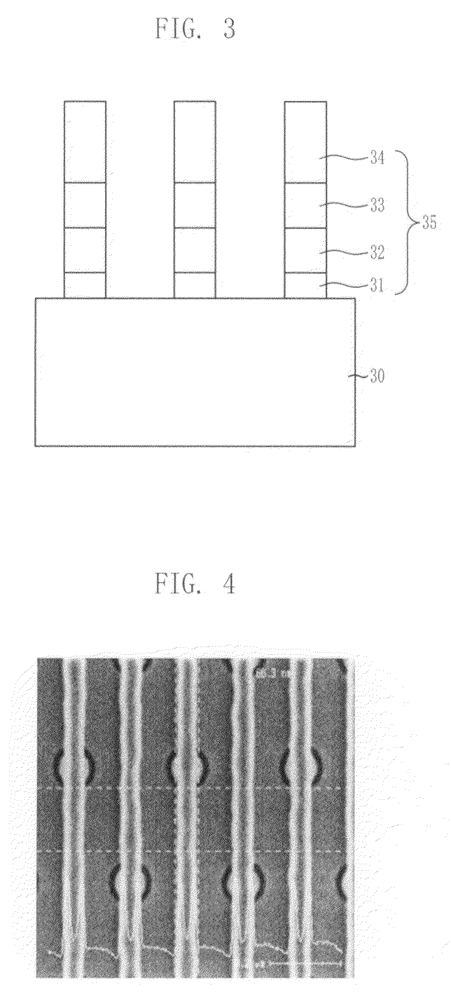

FIG. 3 is a cross-sectional view illustrating a method for forming a pattern (e.g., bit line pattern) in a semiconductor device in accordance with an embodiment of the present invention. A patterned barrier layer 31 for use in a bit line is formed over a substrate 30 where predetermined bottom structures are already formed. The patterned barrier layer 31 is formed in a titanium (Ti)/titanium (TiN) structure. A conductive structure including a patterned tungsten layer 32 and a patterned polysilicon layer 33 is formed over the patterned barrier layer 33. A hard mask pattern 34 is formed over the conductive structure.

In more detail of this patterning, although not shown, a barrier layer, a tungsten layer, a polysilicon layer, and a hard mask layer are formed over the substrate 30. The hard mask layer includes a nitride-based material. A photoresist pattern (not shown) is formed over the hard mask layer, which is subsequently etched using the photoresist pattern as an etch mask to provide the hard mask pattern 34. The polysilicon layer, the tungsten layer and the barrier layer are etched using the hard mask pattern 34 as an etch barrier to thereby provide the patterned polysilicon layer 33, the patterned tungsten layer 32, and the patterned barrier layer 31. Although the etch target in the present embodiment includes a structure where the barrier layer (i.e., the Ti/TiN layer), the tungsten layer, and the polysilicon layer are sequentially formed over the substrate 30, the etch target may include one selected from a group consisting of Ti, TiN, tungsten, polysilicon, and a combination thereof.

The above patterning proceeds with using a gas mixture including a fluorine (F)-based gas and bromine (Br)-based gas. The gas mixture has a lower etch rate to nitride compared to the lower layer to prevent damage and loss of hard mask pattern 34. By using the gas mixture including the F-based gas and Br-based gas, damage on a top region of the hard mask pattern 34 can be prevented due to the etch rate difference. This effect is pronounced by the Br-based gas that produces polymers laminated over the hard mask pattern 34.

More particularly, the F-based gas includes one selected from a group consisting of SF₆ gas, NF₃ gas, CF₄ gas and a combination thereof. The F-based gas flows at a rate of about 15 sccm to 150 sccm. The Br-based includes HBr-based gas, and flows at a rate of about 100 sccm to 500 sccm. A pressure of an etching chamber is kept at about 10 mTorr to 150 mTorr.

Following Table 1 shows etch rates of various layers using the above gas mixture including the F-based gas and the Br-based gas in the aforementioned etch condition.

TABLE 1

| | Layer type | | | |
|---|---|---|---|---|
| | Nitride | Polysilicon | Tungsten | TiN |
| | layer | layer | layer | layer |
| Etch rate(Å/min) | 175 | 1,700 | 1,500 | 1,800 |

As shown in Table 1, in the case of using the F-based gas and the Br-based gas, the etch rate of the nitride layer is about 175 Åper minute. This etch rate is relatively lower than etch rates of the polysilicon layer, the tungsten layer and the TiN layer. Therefore, in the lower layers including the polysilicon layer, the tungsten layer, and the barrier layer using the hard mask pattern 34 as an etch mask and this gas mixture as an etch gas, the damage and loss of the top region of the hard mask pattern 34 can be decreased. This effect is pronounced by the lamination of polymers, produced by the Br-based gas, over the hard mask pattern layer 34.

FIG. 4 is a top view of a bit line pattern in accordance with an embodiment of the present invention. A top portion of a hard mask (e.g., nitride-based hard mask) rarely sustains damage or loss during forming of the bit line pattern in accordance with an embodiment of this present invention. Therefore, a self-aligned contact (SAC) process margin for a subsequent SAC process can be secured and stability of the process increases.

In this description, forming a bit line pattern in a semiconductor device is explained as an exemplary implementation of the present invention. However, the present invention should not be confined within this implementation and can be applied to any technology of forming patterns by etching a lower layer using the above illustrated hard mask (e.g., nitride-based hard mask). For example, the present invention can be applied to the line type patterns such as word lines and metal wiring or to hole type patterns.

According to various embodiments of the present invention, the method for forming a pattern in a semiconductor device can minimize damage and loss of the hard mask by etching the lower layer of the hard mask using the F-based gas and Br-based gas.

While the present invention has been described with respect to the specific embodiments, it will be apparent to those skilled in the art that various changes and modifications may be made without departing from the spirit and scope of the invention as defined in the following claims.

What is claimed is:

1. A method for forming a target pattern in a semiconductor device, comprising:
forming an etch target layer over a substrate;
forming a hard mask pattern over the etch target layer; and
etching the etch target layer using the hard mask pattern as an etch mask and a gas mixture including a fluorine (F)-based gas and a bromine (Br)-based gas as an etch gas to form the target pattern.

2. The method of claim 1, wherein the F-based gas includes one selected from a group consisting of SF₆ gas, NF₃ gas, CF₄ gas, and a combination thereof.

3. The method of claim 2, wherein the F-based gas flows at a rate of about 15 sccm to 150 sccm.

4. The method of claim 1, wherein the Br-base gas includes HBr-gas.

5. The method of claim 4, wherein the Br-based flows at the rate of about 100 sccm to 500 sccm.

6. The method of claim 1, wherein etching the etch target layer comprises performing the etching under a pressure of about 10 mTorr to 150 mTorr.

7. The method of claim 1, wherein the Br-based gas produces polymers, the polymers laminated over the hard mask pattern.

8. The method of claim 1, wherein the gas mixture including the F-based gas and the Br-based gas has a lower etch rate to the hard mask pattern compared to the etch target layer.

9. The method of claim 1, wherein the hard mask pattern includes a nitride-based material.

10. The method of claim 1, wherein the etch target layer comprises one selected from a group consisting of a titanium (Ti) layer, a titanium nitride layer, a tungsten (w) layer, a polysilicon layer, and a combination thereof.

11. The method of claim 1, wherein the etch target layer is formed by sequentially stacking a titanium (Ti)/titanium nitride (TiN) layer, a tungsten (W) layer, and a polysilicon layer.

12. The method of claim 1, wherein the etch target pattern includes one of a bit line pattern, a word line pattern, and a metal line pattern.
